(19) United States
(12) Patent Application Publication
(10) Pub. No.: US 2005/0247260 A1
(43) Pub. Date: Nov. 10, 2005

(54) Non-polar single crystalline a-plane nitride semiconductor wafer and preparation thereof

(76) Inventors: Hyunmin Shin, Seoul (KR); Hae-Yong Lee, Kwangmyeong-si (KR); Changho Lee, Suwon-si (KR); Hyun-Suk Kim, Cheonan-si (KR); Chong-Don Kim, Seongnam-si (KR); Sun-Hwan Kong, Hwaseong-gun (KR)

Correspondence Address: David A. Einhorn, Esq.;Anderson Kill & Olick, P.C., 1251 Avenue of the Americas, New York, NY, 10020, US

(21) Appl. No.: 11/117,683

(22) Filed: Apr. 28, 2005

(30) Foreign Application Priority Data
May 7, 2004 (KR) 10-2004-0032195

(51) Int. Cl. C30B 25/00

(52) U.S. Cl. 117/88

(57) ABSTRACT

A single crystalline a-plane nitride semiconductor wafer having no voids, bending or cracks can be rapidly and effectively prepared by hydride vapor phase epitaxy (HVPE) growth of the a-plane nitride semiconductor film on a single crystalline r-plane sapphire substrate at a temperature ranging from 950 to 1,100° C. and at a rate ranging from 30 to 300 μm/hr.

### FIELD OF THE INVENTION

The present invention relates to a non-polar single crystalline a-plane nitride semiconductor wafer having no voids, bending or cracks, and a method for preparing said nitride semiconductor wafer.

### BACKGROUND OF THE INVENTION

Single crystalline nitride-based wafers employed as substrates in manufacturing semiconductor devices are mostly c-plane ({0001}-plane) thin films which are grown on c-plane sapphire substrates by a conventional method, e.g., metal organic chemical vapor deposition (MOCVD), molecular beam epitaxy (MBE) and hydride vapor phase epitaxy (HVPE), and then separated therefrom.

Such c-plane nitride films grown on c-plane sapphire substrates, however, tend to generate cracks due to the differences in the lattice parameter and thermal expansion coefficient at the interface during a growth process. This crack problem is more serious in case of c-plane nitride films doped with elements such as silicon. Also, the c-plane nitride films, for example GaN/AlGaN heterostructures over c-plane sapphire or (0001) SiC substrates, possess spontaneous or piezoelectric polarization field along the polar c-axis of the wurtzite crystal structure. These polarization discontinuities generate at interfaces between adjacent device layers fixed sheet charges which give rise to internal electric fields. These polarization-induced electric fields spatially separate electrons and hole wavefunctions in quantum well structures, thereby reducing internal quantum efficiencies and significantly altering the electronic and optical properties of the device.

In contrast to the c-plane nitride films, a-plane ({11-20}-plane) nitride films grown on r-plane ({1-102}-plane) sapphire substrates are non-polar, thus exhibit no polarization field and quantum confined Stark effect, and can be advantageously used for high efficiency light-emitting diodes and high power microwave transistors.

Nevertheless, such a-plane nitride film substrates are not yet commercially available for the reason that when an a-plane nitride film is grown on an r-plane substrate, it attains an uneven surface morphology with {1010}-plane ridges extended toward the <0001> direction (see FIG. 1) and internal macro-voids due to the lack of coalescence of these ridges. The above surface irregularity and the macro defects limit fabrication and performance of the multi-layer device.

U.S. Patent Publication No. 2003-198837 describes a method of growing 1.5 μm thick a-plane gallium nitride (GaN) films with planar surfaces on r-plane sapphire substrates by forming a low temperature GaN buffer layer having an 100 nm-thickness prior to a high temperature growth of the a-plane GaN film at a low pressure by MOCVD. However, this method is not appropriate for the formation of a thick film of 30 μm or more which is useful as a freestanding substrate.

### SUMMARY OF THE INVENTION

Accordingly, it is an object of the present invention to provide a high quality non-polar single crystalline a-plane nitride semiconductor wafer having no voids, bending or cracks.

It is another object of the present invention to provide an effective method for preparing said nitride semiconductor wafer.

In accordance with one aspect of the present invention, there is provided a single crystalline a-plane nitride semiconductor wafer having a thickness of 130 μm or more obtained by conducting hydride vapor phase epitaxy (HVPE) on a single crystalline r-plane sapphire substrate.

In accordance with another aspect of the present invention, there is provided a method for preparing a single crystalline a-plane nitride semiconductor wafer which comprises growing at a rate of 30 to 300 μm/hr the a-plane nitride film on a single crystalline r-plane sapphire substrate heated to a temperature ranging from 950 to 1,100° C. by hydride vapor phase epitaxy (HVPE), separating the grown a-plane nitride film from the substrate, and polishing the surface thereof.

### BRIEF DESCRIPTION OF THE DRAWINGS

The above and other objects and features of the present invention will become apparent from the following description of the invention, when taken in conjunction with the accompanying drawings, which respectively show:

FIG. 1: schematic diagrams which show the differences in the lattice parameter in case of heteroepitaxial growth of a single crystalline a-plane nitride thick film on a single crystalline r-plane sapphire substrate and the ridge-like surface morphology of the grown nitride film;

FIG. 2: the steps for preparing a single crystalline a-plane nitride wafer in accordance with one preferred embodiment of the inventive method;

FIG. 3: micro-cracks generated inside an r-plane sapphire substrate when a single crystalline a-plane nitride thick film is grown on the sapphire substrate in accordance with the inventive method;

FIGS. 4 and 5: a photograph and an X-ray diffraction (XRD) pattern of the a-plane GaN thick film (before polishing) obtained in Example 1, respectively;

FIG. 6: a photograph of the a-plane GaN thick film (after separation and polishing) obtained in Example 1;

FIGS. 7A and 7B: a scanning electron microscope (SEM) photograph and an XRD rocking curve of the surface of the a-plane GaN thick film (before polishing) obtained in Example 1, respectively; and

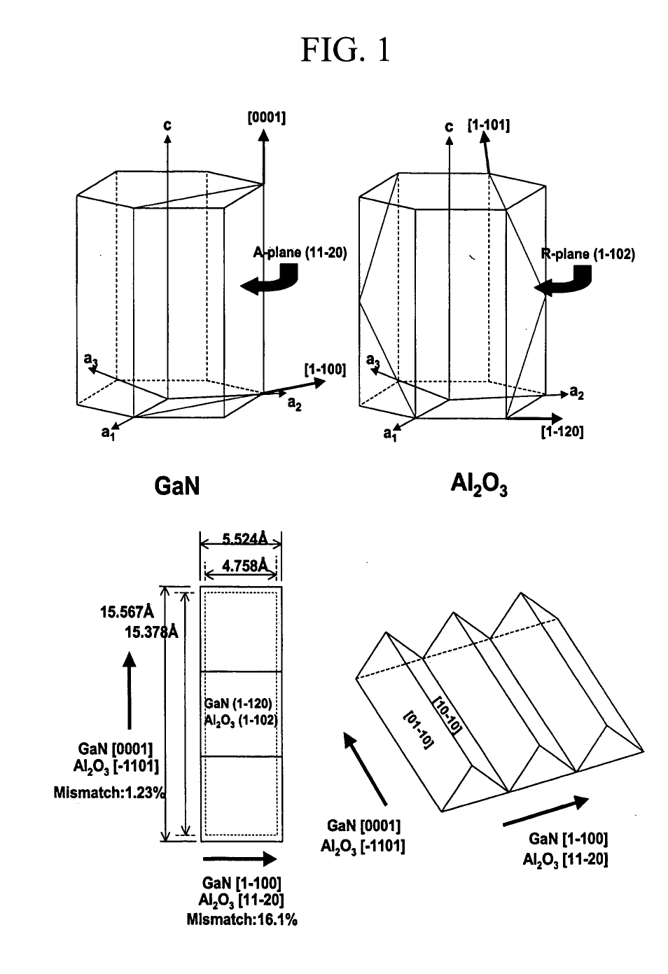

FIGS. 8A and 8B: an SEM photograph and an XRD rocking curve of the surface of the a-plane GaN thick film (before polishing) obtained in Example 2, respectively.
11: single crystalline r-plane sapphire substrate
12: nitridated surface of the r-plane sapphire substrate
13: single crystalline a-plane nitride semiconductor thin film
14: single crystalline a-plane nitride semiconductor thick film
20: polished freestanding a-plane nitride semiconductor wafer

### DETAILED DESCRIPTION OF THE INVENTION

The present invention is characterized in that a non-polar single crystalline a-plane nitride semiconductor wafer having no voids, bending or cracks is prepared by growing the nitride semiconductor film on an r-plane sapphire substrate at a rate of 30 to 300 μm/hr and at a temperature ranging from 950 to 1,100° C. by HVPE.

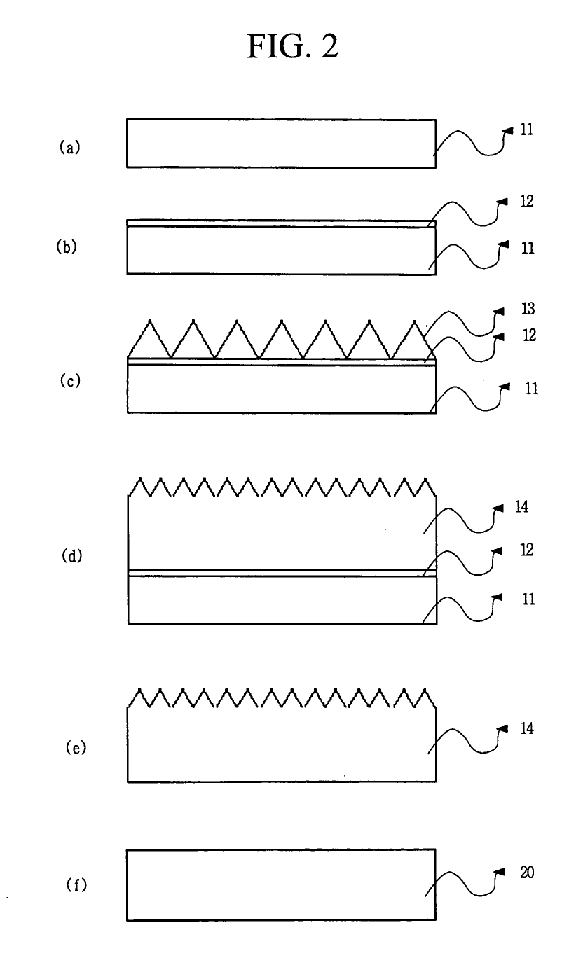

FIG. 2 illustrates the series of steps for preparing a single crystalline a-plane nitride wafer as a freestanding plate in accordance with one preferred embodiment of the inventive method, the steps comprising; (a) preparing a single crystalline r-plane sapphire substrate (11), (b) nitridating one surface of the sapphire substrate (11), (c) growing a single crystalline a-plane nitride semiconductor thin film (13) on the nitridated surface of the substrate (12) using HVPE in accordance with the inventive method, (d) continuing the growth of the nitride film (13) to form a coalesced a-plane nitride semiconductor thick film (14), (e) separating the nitride film (14) from the substrate (11), and (f) polishing a surface of the separated nitride film to form a planar a-plane nitride semiconductor freestanding plate (20).

The nitride compound semiconductor grown on the substrate may be a nitride of at least one III-group element selected from the group consisting of Ga, Al and In, which is represented by formula [AlₓGa_{y}In_{1-x-y}N] (0≦x≦1, 0≦y≦1, 0≦x+y≦1). Besides sapphire (α-Al₂O₃), any one of conventional materials such as ZnO, Si, SiC, lithium aluminate, lithium gallite, GaAs and GaN may be employed as the r-plane substrate.

In accordance with the inventive method, the a-plane nitride semiconductor film may be grown on the r-plane sapphire substrate by hydride vapor phase epitaxy (HVPE) at a growth rate of 30 to 300 μm/hr, preferably 30 to 200 μg/m/hr, by way of bringing the vapor of a chloride of a III-group element and gaseous ammonia (NH₃) into contact with the surface of the substrate maintained at a temperature ranging from 950 to 1,100° C. When the growth temperature is lower than 950° C., the crystallinity of the nitride film becomes poor, and when higher than 1,100° C., the growth rate and crystallinity become low due to the decomposition of the grown nitride crystals. In case the growth rate is higher than 300 μg/m/hr, the deterioration of the crystallinity of the nitride film is also observed due to insufficient time for the constituents to diffuse to an appropriate crystal lattice site.

The vapor of the chloride of the III-group element may be generated in the HVPE reactor by placing one or more III-group elements on a vessel and introducing gaseous hydrogen chloride (HCl) thereto. The reactor chamber may be maintained at a temperature ranging from 600 to 900° C. under an ambient pressure. The gaseous hydrogen chloride and ammonia may be introduced at a volume ratio of 1:2˜20, preferably of 1:2˜5. Provided in the former case is an a-plane nitride film having an FWHM (full width at half maximum) value of 1,000 arcsec or less in an X-ray diffraction (XRD) rocking curve, and in the latter case, an a-plane nitride film having an FWHM value of 500 arcsec or less is obtained. The reduction in the FWHM value is indicative of enhanced crystallinity.

If necessary, the surface of the r-plane sapphire substrate may be nitridated by way of bringing a gas mixture of ammonia (NH₃) and hydrogen chloride (HCl) into contact therewith at a temperature ranging from 900 to 1,100° C. In addition, for the purpose of enhancing the nitridation, the surface of the substrate may be further treated with gaseous ammonia (NH₃) before or after the above nitridation step. Such nitridation of the substrate surface may be performed in an HVPE reactor. The nitridation technique using an ammonia (NH₃)— hydrogen chloride (HCl) gas mixture is disclosed in U.S. Pat. No. 6,528,394 which is incorporated by reference in the present invention.

The a-plane nitride film growth on the r-plane substrate by HVPE at a growth temperature ranging from 950 to 1,100° C. and a growth rate ranging from 30 to 300 μm/hr allows the <0001> directional ridges present in the nitride film surface to coalesce with each other, resulting in the formation of the desired a-plane nitride thick film having no voids.

Further, such an a-plane nitride film growth leads to the formation of micro-cracks inside the underlying substrate due to large anisotropy of the internal stress as shown in FIG. 3. The micro-cracks formed inside the substrate do not interconnect but act to reduce the internal stress generated in the nitride film, thereby giving no adverse effects on the shape of the substrate or the nitride film formed thereon.

Thus, in the inventive method, the a-plane nitride thick film having a thickness of 130 μm or more, preferably of 150 μm or more, more preferably of 300 μm or more, and a diameter of 25 mm, preferably of 50.8 mm (2 inch) can be grown without any voids, bending and cracks. In particular, the nitride film may be grown to an unlimited thickness.

Then, the grown a-plane nitride film may be separated from the substrate and the surface of the separated nitride film may be polished by conventional methods to obtain an improved a-plane nitride wafer with smooth surfaces.

As described above, the present invention provides for the first time a high quality non-polar single crystalline a-plane nitride semiconductor wafer having no voids, bending or cracks that can be used as a freestanding plate for the manufacture of a light-emitting diode (LED).

The following Examples are given for the purpose of illustration only, and are not intended to limit the scope of the invention.

### EXAMPLE 1

A single crystalline r-plane sapphire substrate with a 50.8 mm-diameter was loaded in an HVPE reactor, and nitridated at 950˜1,100° C. successively with gaseous ammonia, a gas mixture of ammonia and hydrogen chloride, and gaseous ammonia.

On the nitridated substrate thus obtained, a gallium nitride single crystal film was allowed to grow at a rate of 75 μm/hr by bringing gaseous gallium chloride and gaseous ammonia into contact therewith at 1,000° C. The gallium chloride gas, generated by reacting gallium with hydrogen chloride, and the gaseous ammonia were introduced through two separate inlets at a gaseous hydrogen chloride:ammonia volume ratio of 1:6. The reactor chamber was maintained at a temperature ranging from 600 to 900° C. under an ambient pressure. The growth of gallium nitride single crystal film was conducted for 400 minutes to form a 500 μm-thick gallium nitride semiconductor film on the substrate.

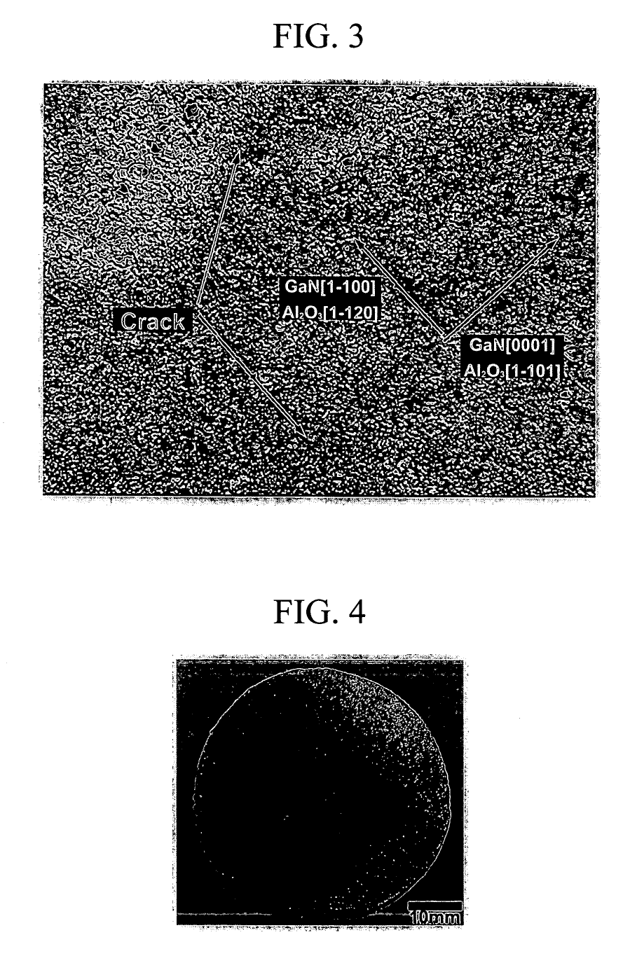

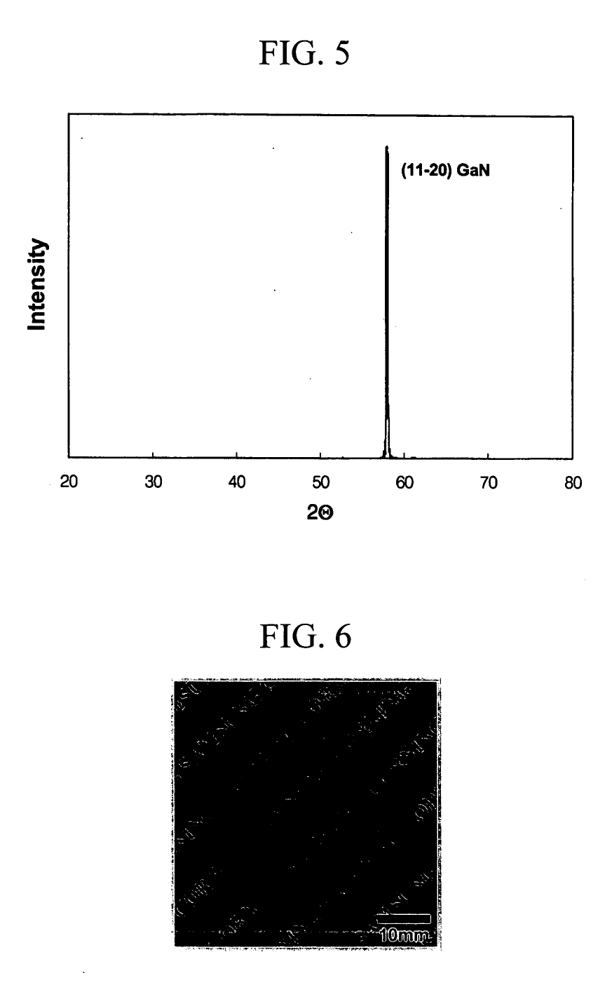

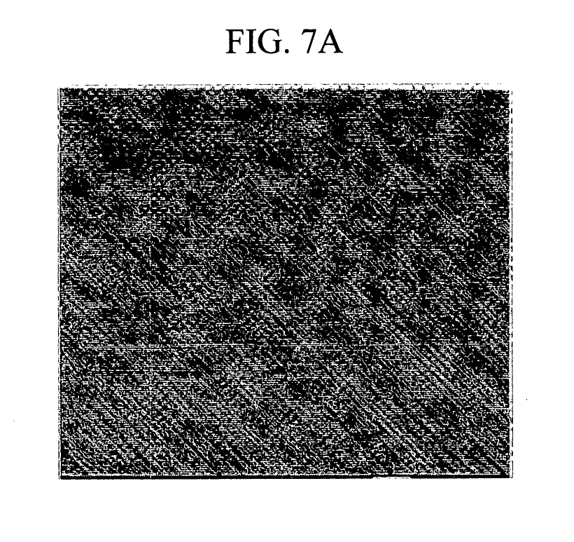

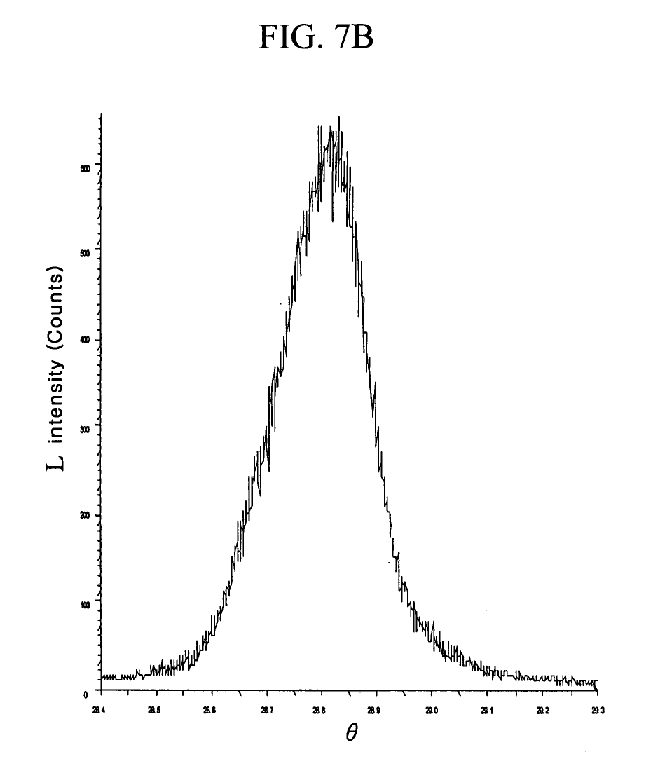

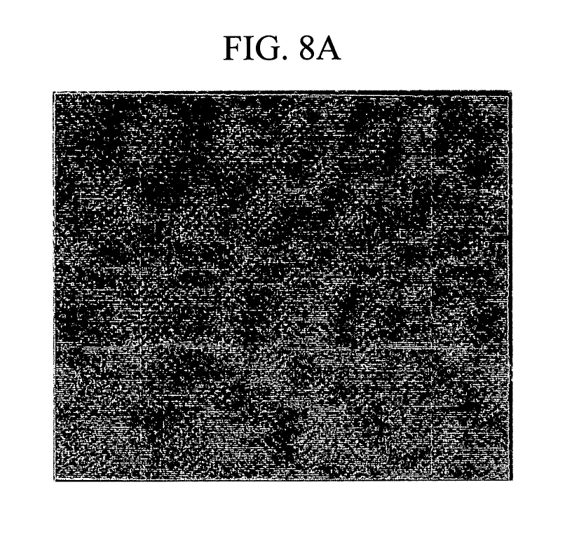

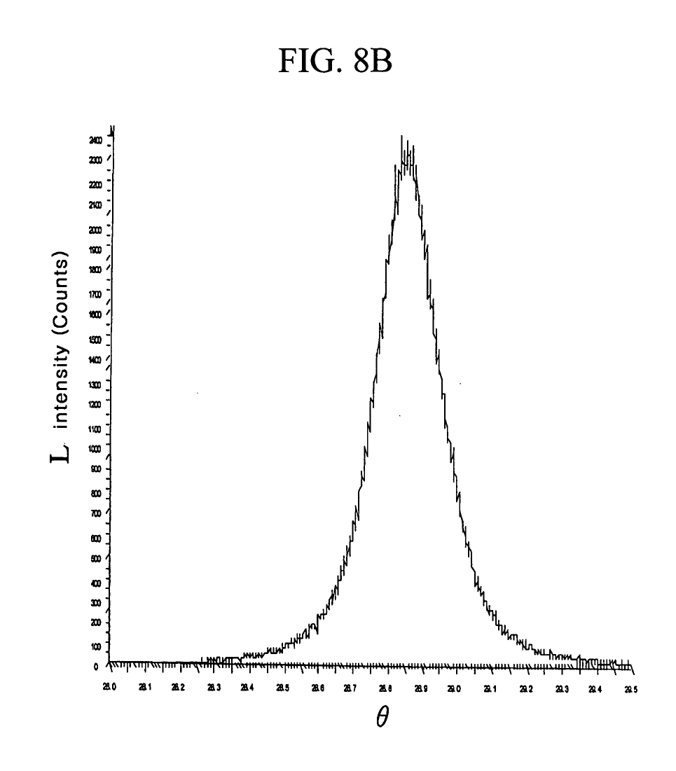

A photograph and an X-ray diffraction (XRD) pattern of the a-plane GaN thick film thus formed are shown in FIGS. 4 and 5, respectively. A scanning electron microscope (SEM) photograph and an XRD rocking curve of the surface thereof are shown in FIGS. 7A and 7B, respectively. The XRD rocking curve of FIG. 7B suggests that the a-plane nitride film with an FWHM (full width at half maximum) value of 871 arcsec was obtained.

Then, the grown a-plane nitride film was separated from the substrate using a 355 nm Q-switched Nd:YAG excimer laser. The surface of the separated nitride film was polished using a wafer lapping and polishing machine to obtain a 400 μm-thick gallium nitride freestanding plate.

A photograph of the resultant a-plane GaN plate is shown in FIG. 6, which confirms it is a smooth plate with no surface defects.

### EXAMPLE 2

The procedure of Example 1 was repeated except that the volume ratio of the gaseous hydrogen chloride and ammonia was in the range of 1:2˜5, to form a 500 μm-thick gallium nitride semiconductor film on the sapphire substrate.

An SEM photograph and an XRD rocking curve of the surface of the a-plane GaN thick film thus formed are shown in FIGS. 8A and 8B, respectively. The XRD rocking curve of FIG. 8B reveals that the a-plane nitride film possesses an FWHM value of 342 arcsec, the smallest among the hitherto-reported values, which indicates that the film crystallinity was significantly enhanced.

As described above, in accordance with the method of the present invention, a high quality non-polar single crystalline a-plane nitride semiconductor wafer having no voids, bending or cracks may be rapidly and effectively prepared and it may be advantageously used as a substrate in the manufacture of an LED.

While the invention has been described with respect to the above specific embodiments, it should be recognized that various modifications and changes may be made to the invention by those skilled in the art which also fall within the scope of the invention as defined by the appended claims.

1. A single crystalline a-plane ({11-20}-plane) nitride semiconductor wafer having a thickness of 130 μm or more.

2. The a-plane nitride semiconductor wafer of claim 1 which has a thickness of 150 μm or more.

3. The a-plane nitride semiconductor wafer of claim 1 which has a thickness of 300 μm or more.

4. The a-plane nitride semiconductor wafer of claim 1 which is grown on a single crystalline r-plane ({1-102}-plane) sapphire substrate.

5. The a-plane nitride semiconductor wafer of claim 1 which is grown by hydride vapor phase epitaxy (HVPE).

6. The a-plane nitride semiconductor wafer of claim 1 which has a diameter of 25 mm or more.

7. The a-plane nitride semiconductor wafer of claim 1 which has a diameter of 50.8 mm or more.

8. The a-plane nitride semiconductor wafer of claim 4 which, after grown, is separated from the substrate and then polished.

9. The a-plane nitride semiconductor wafer of claim 1 which has an FWHM (full width at half maximum) value of 1,000 arcsec or less in an X-ray diffraction (XRD) rocking curve.

10. The a-plane nitride semiconductor wafer of claim 1 which has an FWHM (full width at half maximum) value of 500 arcsec or less in an X-ray diffraction (XRD) rocking curve.

11. The a-plane nitride semiconductor wafer of claim 1 which is used as a freestanding plate in the manufacture of light-emitting diodes.

12. The a-plane nitride semiconductor wafer of claim 1 which is composed of a nitride of at least one III-group element selected from the group consisting of Ga, Al and In.

13. A method for preparing the a-plane nitride wafer of claim 1 which comprises growing at a rate of 30 to 300 μg/m/hr the a-plane nitride film on a single crystalline r-plane sapphire substrate heated to a temperature ranging from 950 to 1,100° C. by hydride vapor phase epitaxy (HVPE), separating the grown a-plane nitride film from the substrate, and polishing the surface thereof.

14. The method of claim 13, wherein the growth of the a-plane nitride film is conducted by bringing the vapor of a chloride of a III-group element and gaseous ammonia (NH₃) into contact with the surface of the substrate in a reactor chamber, the vapor of the chloride of the III-group element being generated through a reaction between the III-group element and gaseous hydrogen chloride.

15. The method of claim 14, wherein the volume ratio of the gaseous hydrogen chloride and ammonia is in the range of 1:2˜20.

16. The method of claim 14, wherein the volume ratio of the gaseous hydrogen chloride and ammonia is in the range of 1:2˜5.

17. The method of claim 13, wherein the surface of the r-plane sapphire substrate for the growth is nitridated by treating with a gas mixture of ammonia (NH₃) and hydrogen chloride (HCl).

18. The method of claim 13, wherein the growth of the a-plane nitride film continues until a desired thickness thereof is achieved.
